(19) United States
(12) Patent Application Publication
(10) Pub. No.: US 2012/0074961 A1
(43) Pub. Date: Mar. 29, 2012

(54) CAPACITIVE SENSOR WITH ACTIVE SHIELD ELECTRODE

(75) Inventor: FREDERICK P. HERRMANN, Sharon, MA (US)

(73) Assignee: Kopin Corporation, Taunton, MA (US)

(21) Appl. No.: 13/246,394

(22) Filed: Sep. 27, 2011

Related U.S. Application Data
(60) Provisional application No. 61/387,771, filed on Sep. 29, 2010.

(51) Int. Cl. G01R 27/26

(52) U.S. Cl. 324/658

(57) ABSTRACT

A capacitive sensor having an active shield electrode driven by a unity gain amplifier. Various arrangements using multiplexors or switch arrays may allow single shield with multiple sense electrodes.

### RELATED APPLICATION

This application claims the benefit of U.S. Provisional Application No. 61/387,771, filed on Sep. 29, 2010. The entire teachings of the above application(s) are incorporated herein by reference.

### INTRODUCTION

Capacitive touch sensors are replacing switches, buttons, and knobs in new consumer electronics applications. The most famous is perhaps the circular dial on the Apple® iPod, but capacitive sense inputs are now common even on more mundane products, such as household appliances. Advantages of these touch inputs include reliability (no moving parts), lower manufacturing costs, operation in wet or dusty environments, and stylish design.

Integrated circuit makers have introduced products to support capacitive touch sensors. A company called Microchip Technology, Inc. touts the “mTouch” capabilities of their microcontrollers, and Cypress Semiconductor Corporation's “PSoC Programmable System-on-Chip” products support “CapSense” inputs. These companies publish application notes with layout recommendations for capacitive sensors as follows:
[1] “Capacitance Sensing—Layout Guidelines for PSoC CapSense.” AN2292. Cypress Semiconductor Corporation. Document No. 001-41439 Rev. *A. Jan. 11, 2008;
[2] “Layout and Physical Design Guidelines for Capacitive Sensing.” AN1102. DS01102A. Microchip Technology Inc. 2007; and
[3] “Techniques for Robust Touch Sensing Design.” AN1334. DS01334A. Microchip Technology Inc. 2010

FIG. 1 illustrates a capacitive touch sensor, with finger capacitance C_{F} and parasitic capacitance C_{P}. taken from reference [3]. The finger capacitance C_{F} increases as the finger approaches the sensor. The sensing circuit measures total capacitance C_{TOT}=C_{F}+C_{P}. It is desirable to minimize C_{P} to improve sensitivity.

FIG. 2 is also taken from reference [3], and shows a sensor sandwiched between a printed circuit board (lower dark shaded area) and a cover dielectric (lighter top area). The “field lines” do not appear to be drawn quite correctly, but they do illustrate the extent of sensitivity both above and below the sensor.

To reduce the parasitic capacitance C_{P} and maximize sensitivity, it is desirable to keep the back side of the PCB free of conductive components. However, this goal may conflict with shielding requirements for noise immunity and electromagnetic compatibility. Application note [3] referenced above discusses the possible compromises, and suggests the several approaches summarized in FIG. 3.

### SUMMARY

In preferred embodiments, a capacitive sensor circuit includes a capacitive touch sense electrode. An active shield electrode is placed near but spaced apart from the capacitive sense electrode. An amplifier, preferably arranged as a unity gain amplifier, is connected between the sense electrode and the active shield electrode. With this arrangement, the parasitic capacitor of the sense electrode is effectively reduced, thereby increasing sensitivity.

The amplifier may be an operational amplifier, an MOS source follower, or other type of amplifier.

The amplifier may be other than a unity gain amplifier.

In some embodiments, the active shield electrode may be disposed on an opposite side of a printed circuit board or flexible printed circuit or other substrate on which the sense electrode is disposed. The active shield can also be placed on the same side of a substrate and surround one or more areas of the sense electrode.

The active shield may be placed between multiple sense electrodes.

In further embodiments, the active shield electrode may be a buried electrode placed in a internal layer of a multi-layer printed circuit board, flexible printed circuit board or other substrate. One of the other layers may provide a third ground shield electrode.

In still other arrangements, requiring multiple sense electrodes, there may be multiple corresponding active shield electrodes. A single, shared, active shield electrode may be serviced by a single unity gain amplifier using multiplexors, switch arrangements, or in other ways.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a diagram of a prior art touch sensor showing finger capacitance, C_{F}, and a parasitic capacitance, C_{P}.

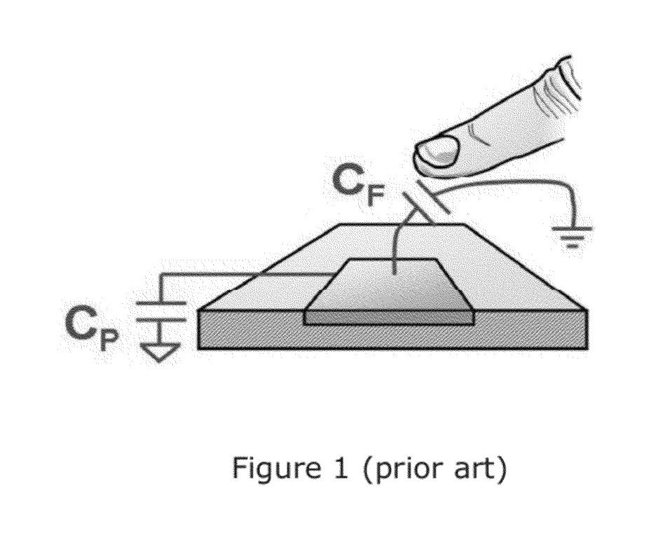

FIG. 2 is a prior art capacitive sensor illustrating field lines.

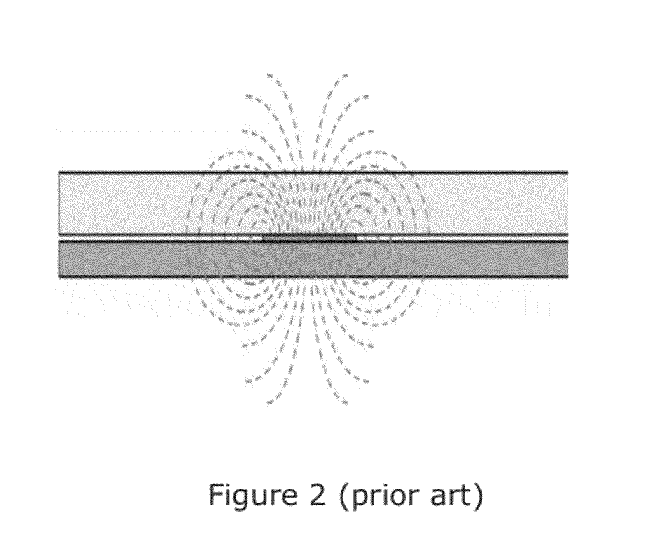

FIG. 3 is a cross-sectional diagram of grounding techniques used in prior art design for high sensitivity or high noise immunity.

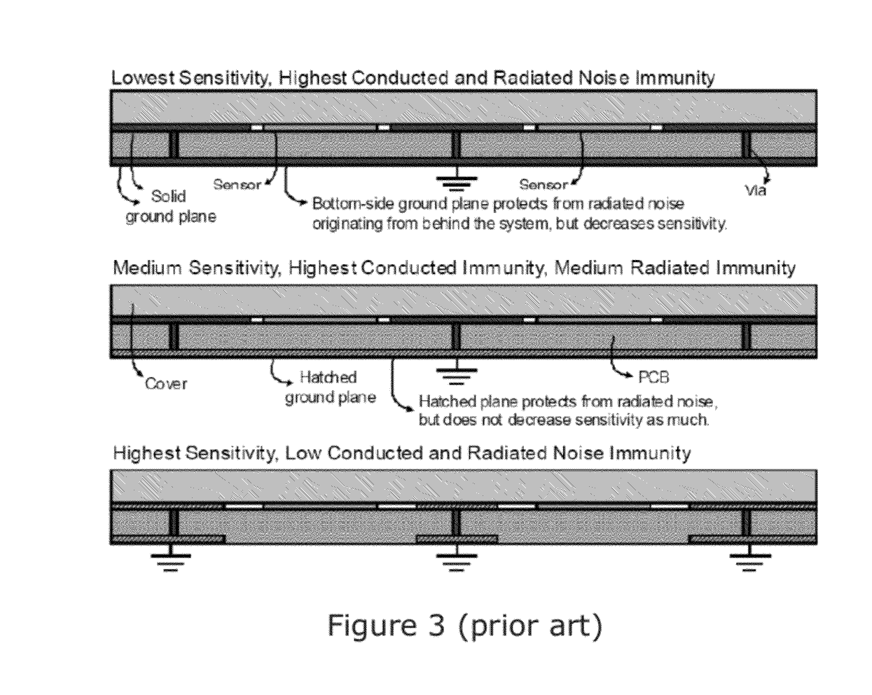

FIG. 4 is a prior art touch-input system with multiple sensors.

FIG. 5 illustrates an improved touch sensor with an active shield electrode placed on back of a substrate such as a Printed Circuit Board (PCB)

FIG. 6 illustrates an improved touch sensor with an active shield on an internal layer of a PCB.

FIG. 7 illustrates the new touch sensor with an active shield and a ground shield.

FIG. 8 is a multi-sensor system with one active shield per sensor.

FIG. 9 is another multi-sensor system with two multiplexors and one amplifier.

FIG. 10 is a multi-sensor system with single multiplexor and single amplifier.

FIG. 11 is a multi-sensor system with switch network and single amplifier

### DETAILED DESCRIPTION OF AN EMBODIMENT

Described herein is an improved way to configure a capacitive touch sense electrode on a substrate.

In addition to the shielding considerations, it would also be desirable to use the back side of the substrate for additional circuitry. However, mounting electrical components on the back side involves similar compromises to sensitivity.

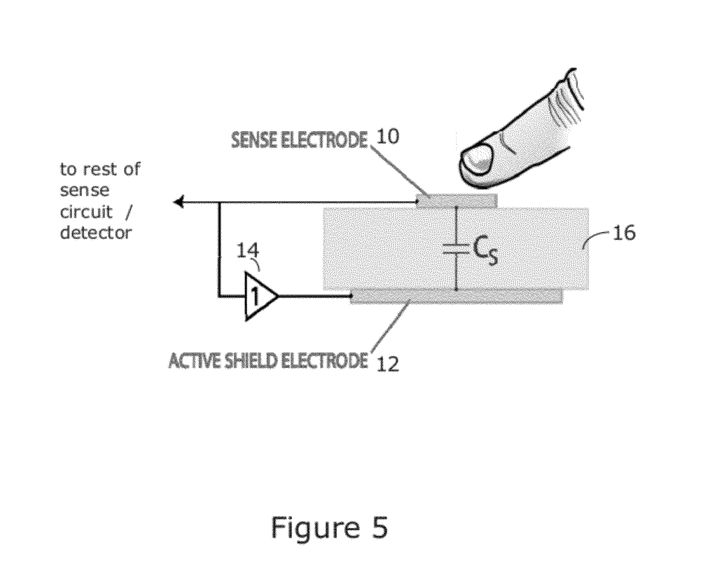

As shown in FIG. 5, parasitic capacitance of a capacitive sense electrode 10 may be effectively reduced by using an active shield electrode 12. The active shield electrode 12 is placed on a substrate, such as a printed circuit board (PCB). The active shield 12 is aligned with the sense electrode 10 on a backside (e.g., a side opposite the sense electrode 10). The active shield electrode 12 is driven with a (preferably) unity gain amplifier 14 to maintain constant DC potential difference between the shield 12 and sense 10 electrodes. As a result, the charge on the sense-to-shield capacitance C_{S} will be unchanged, even as the sensing circuit charges or discharges the sense electrode. For this reason, C_{S} does not contribute to C_{P} and does not reduce the sensitivity of the sensor.

Amplifier 14 may have other than exactly unity gain, and may take different forms, such as a Metal Oxide Semiconductor (MOS) source follower, operational amplifier, etc.

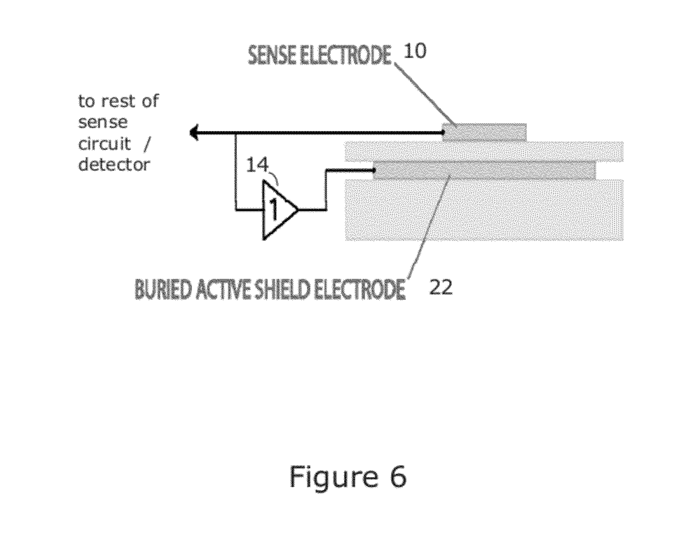

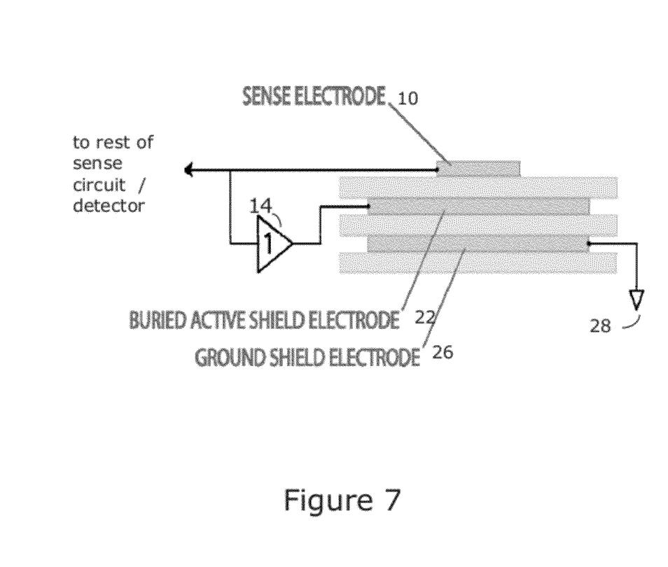

It is also possible to place a “buried” active shield electrode(s) 22 on an internal layer of a PCB (see FIG. 6) or sandwiched between the sense electrode 10 and a ground shield electrode 26 on a third (internal or external) conductive layer (see FIG. 7). The ground shield electrode is coupled to a ground reference point 28 in the latter instance.

Although not shown in the Figures, active shield electrode may also be on the same side, but placed in other locations near, but spaced apart from the sense electrode.

### Multi-Sensor Systems

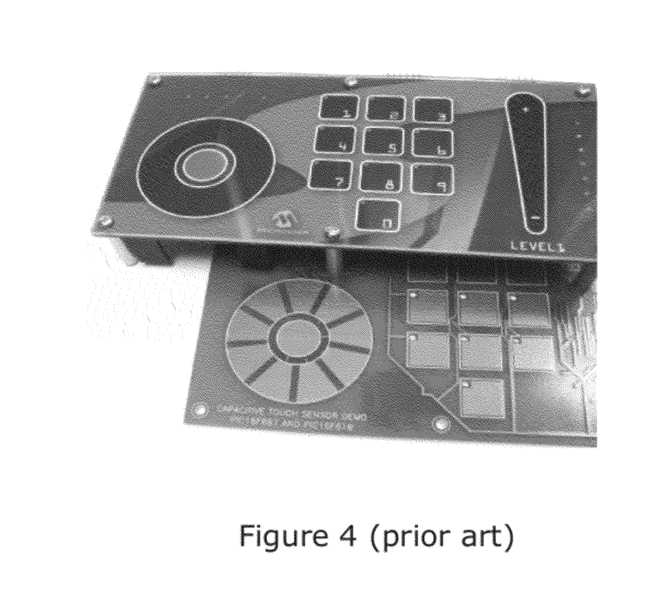

Systems with capacitive touch inputs commonly use multiple sensors to implement keypads or segmented dial and slide controls. (See one example in FIG. 4.) Such systems may scan the sensors sequentially, using a multiplexor to connect the sensors one-by-one to a shared sense circuit.

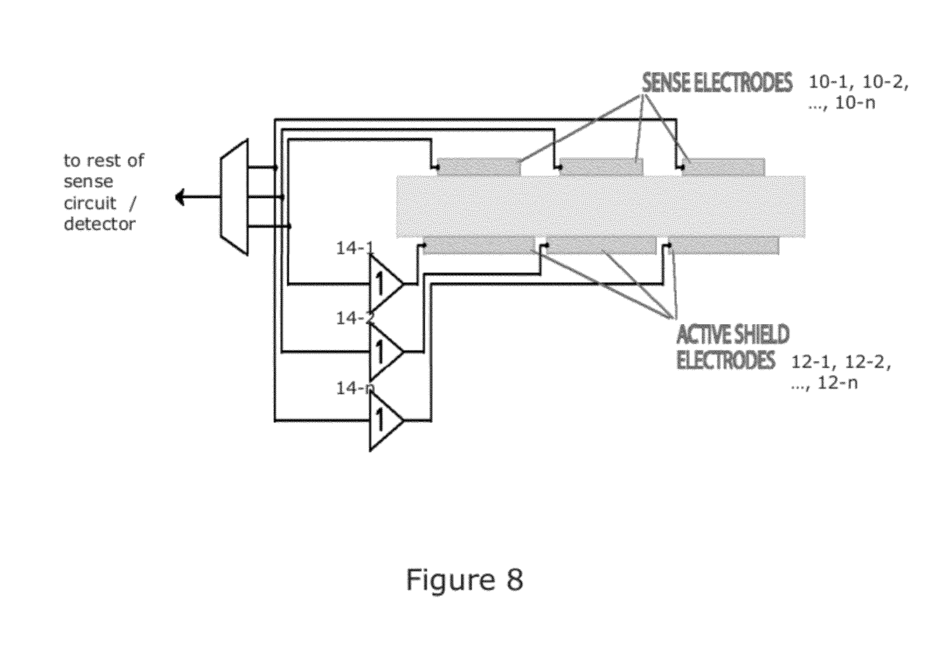

One approach to active shielding for multi-sensor systems is to use multiple active shield electrodes 12-1, 12-2, . . . , 12-n, with one active shield for each sensor 10-1, 10-2, . . . , 10-n. As shown in FIG. 8, with this approach, a unity gain amplifier 14-1, 14-2 . . . , 14-n, is also required for each shield.

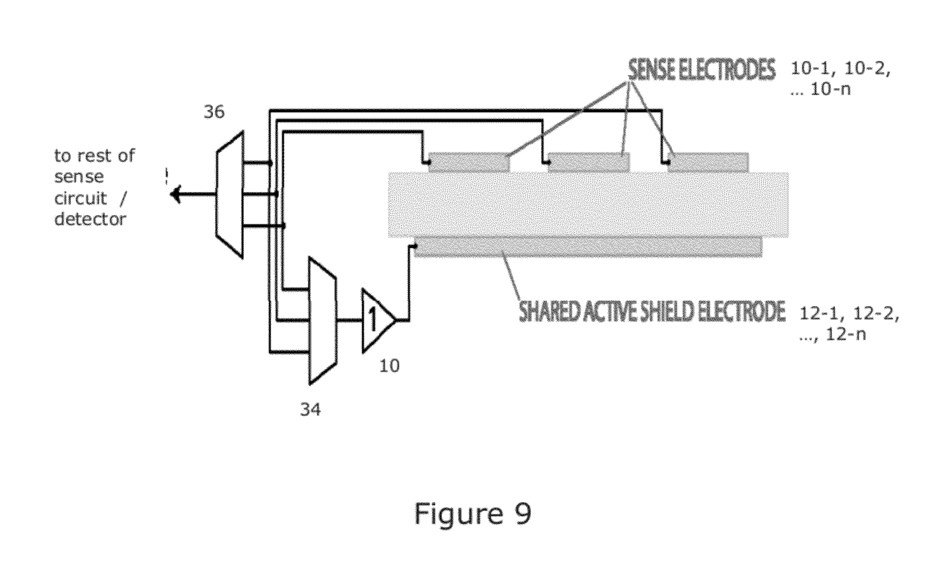

In sequentially-scanned systems, the circuit may be simplified by using a shared active shield electrode 13 among multiple sensors 10-1, 10-2, . . . , 10-n. As shown in FIG. 9, a first multiplexor 34 is used to select one of the active sense electrodes 10-1, 10-2, . . . , 10-n input to a single unity gain amplifier 10. Another multiplexor 36 selects the sense electrode 10-1, 10-2, . . . , 10-n used for sensing. The two multiplexors 36, 34 associated with the sense circuit and with the amplifier must be synchronized so that both access the same sense electrode.

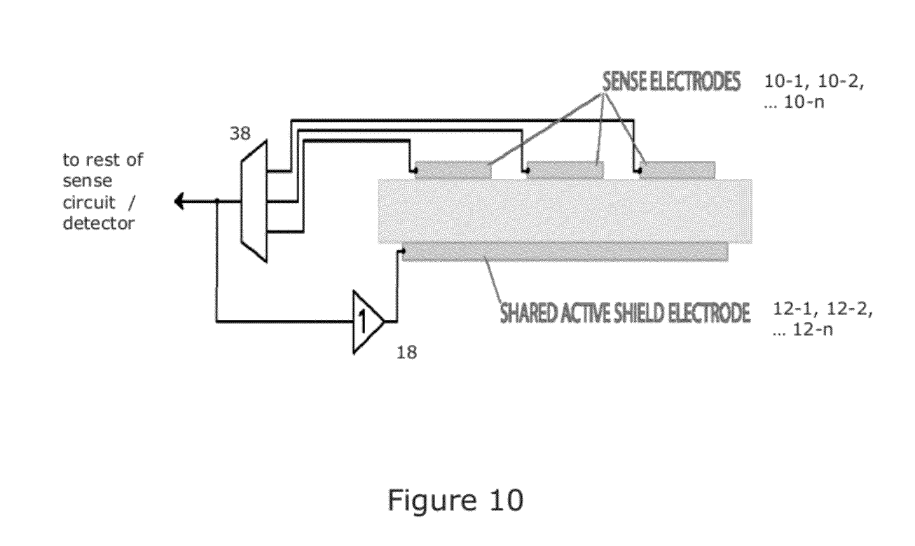

A further implification is shown in FIG. 10, in which the two multiplexors have been combined as single multiplexor 38. This approach may be preferred when the sense circuit and unity gain amplifier, i.e., are integrated in the same integrated circuit. However, it may not be practical for presently-available capacitive sensor chips which may not make the multiplexed sense signal available externally.

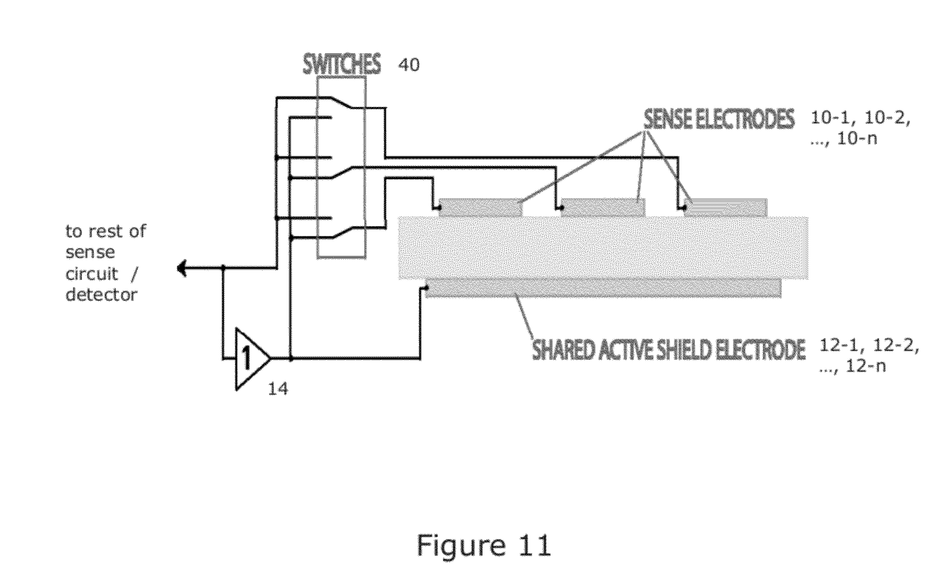

In still another arrangement, the system of FIG. 11 replaces the multiplexor 38 with a switch network 40 controlled such that one active sense electrode 10-1, 10-2, . . . , or 10-n, is switched to the sense circuit while all the remaining sense electrodes are connected to the amplifier 14 output. Thus the unselected sense electrodes function as additional active shields during their inactive phases.

The teachings of all patents, published applications, publications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. A capacitive sensor circuit comprising:
a capacitive sense electrode:
an active shield electrode, spaced apart from the capacitive sense electrode; and
an amplifier, connected between the sense electrode and the active shield electrode.

2. The sensor circuit of claim 1 in which the amplifier is an operational amplifier.

3. The sensor circuit of claim 1 in which the amplifier is an MOS source follower.

4. The sensor circuit of claim 1 wherein the amplifier is a unity gain amplifier.

5. The sensor circuit of claim 1 in which the active shield electrode is disposed on a side of a printed circuit board or flexible printed circuit opposite the sense electrode.

6. The sensor circuit of claim 1 in which the active shield electrode is on a same side of a printed circuit board or flexible printed circuit as, and in a position surrounding, the sense electrode.

7. The sensor circuit of claim 1 in which one or more active shield electrode is placed between multiple sense electrodes.

8. The sensor circuit of claim 1 in which the active shield electrodes(s) are placed on an internal layer of a multi-layer printed circuit board (PCB) or flexible printed circuit (FPC).

9. The sensor circuit of claim 8 in which the active shield electrode is disposed between the sense electrode and a ground shield electrode on a third conductive layer.

10. The sensor circuit of claim 8 in which a back side of the PCB or FPC is used to support additional circuitry.

11. The sensor circuit of claim 1 with multiple sense electrodes, and multiple active shield electrodes with the active shield electrodes driven by respective independent unity gain amplifiers.

12. The sensor circuit of claim 1 with multiple sense electrodes and a shared active shield electrode, the shared active shield electrode driven by a single amplifier, with the amplifier input connected to the active sense electrode via a multiplexor.

13. The sensor circuit of claim 1 with multiple sense electrodes and a shared active shield electrode driven by a single unity gain amplifier, with a single multiplexor connecting the shared active sense electrode to the unity gain amplifier input.

14. The sensor circuit of claim 1 with multiple sense electrodes and a shared active shield electrode driven by a single unity gain amplifier, with a switch network connecting the shaped active sense electrode to the unity gain amplifier input, and connecting the inactive sense electrodes to the unity gain amplifier output.

15. The sensor circuit of claim 1 with multiple sense electrodes and a multiplexor and sense circuit for selecting one of the multiple capacitive sense electrodes as a selected sense electrode, and also integrating an amplifier on a common substrate to drive the active shield electrode while maintaining a constant potential difference between the active shield electrode and the selected sense electrode.
